(19) United States
(12) Patent Application Publication
(10) Pub. No.: US 2025/0261328 A1
(43) Pub. Date: Aug. 14, 2025

(54) PREVENTING LOSS OF POWER TO SERVER RACK DUE TO A FAILURE IN A POWER DELIVERY SYSTEM

(71) Applicant: International Business Machines Corporation, Armonk, NY (US)

(72) Inventors: Edward J. Seminaro, Milton, NY (US); Kevin Robert Covi, Glenford, NY (US)

(21) Appl. No.: 18/439,547

(22) Filed: Feb. 12, 2024

(51) Int. Cl. H05K 7/14

(52) U.S. Cl. CPC H05K 7/1492

(57) ABSTRACT

Described are techniques for preventing loss of power to a server rack due to a failure in a power delivery system. A base management controller in a server of the server rack is configured to monitor for failures in the power supply units providing power to the components of the server. Upon detecting a failure in one or more of the power supply units, the base management controller determines the number of available power supply units supplying power to the components of the server. The base management controller then caps the power drawn by the server in proportion to the number of available power supply units in the server. In this manner, circuit breakers are prevented from being triggered thereby preventing the loss of power for the entire server rack.

### TECHNICAL FIELD

The present disclosure relates generally to data centers, and more particularly to preventing the loss of power to a server rack in a data center employing power oversubscription due to a failure in a power delivery system (e.g., power supply unit, power distribution unit).

### BACKGROUND

A data center is a physical facility that organizations use to house their critical applications and data. A data center's design is based on a network of computing and storage resources that enable the delivery of shared applications and data. The key components of a data center design include routers, switches, firewalls, storage systems, servers, and application-delivery controllers.

### SUMMARY

In one embodiment of the present disclosure, a computer-implemented method for preventing loss of power to a server rack due to a failure in a power delivery system comprises detecting a failure of one or more power supply units providing power to components of a server of the server rack. The method further comprises determining a number of available power supply units in the server in response to detecting the failure of the one or more power supply units. The method additionally comprises capping power drawn by the server in proportion to the number of available power supply units in the server.

Other forms of the embodiment of the computer-implemented method described above are in a system and in a computer program product.

In another embodiment of the present disclosure, a server rack comprises a plurality of servers, where each server of the plurality of servers is powered by a first power distribution unit and a second power distribution unit, and where each server of the plurality of servers comprises a plurality of power supply units configured to provide power to components of the server. Furthermore, each of the first and the second power distribution units operates using three-phase electric power, where each of the first and the second power distribution units distributes power to each pair of power supply units of the plurality of power supply units from one circuit breaker to ensure that each pair of power supply units of the plurality of power supply units operates from a same electrical phase.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a data center, such as a high-availability data center, for practicing the principles of the present disclosure;

FIG. 2 illustrates an internal structure of a server in accordance with an embodiment of the present disclosure;

FIG. 3 illustrates the power distribution unit currents for a server rack with six servers when there are no faults in accordance with an embodiment of the present disclosure;

FIG. 4 illustrates an embodiment of the present disclosure of the hardware configuration of the base management controller which is representative of a hardware environment for practicing the present disclosure;

FIG. 5 is a flowchart of a method for preventing loss of power to a server rack due to a failure in the power delivery system in accordance with an embodiment of the present disclosure;

FIG. 6 illustrates the case of a fault of the power distribution unit with no power capping in accordance with an embodiment of the present disclosure;

FIG. 7 illustrates the case of a fault of the power distribution unit with power capping in accordance with an embodiment of the present disclosure;

FIG. 8 illustrates the case of the loss of a line cord phase on both power distribution units with no power capping in accordance with an embodiment of the present disclosure;

FIG. 9 illustrates the case of the loss of a line cord phase on both power distribution units with power capping in accordance with an embodiment of the present disclosure;

FIG. 10 illustrates the case of a fault of a power supply unit on a power distribution unit for all the servers of the server rack with no power capping in accordance with an embodiment of the present disclosure; and

FIG. 11 illustrates the case of a fault of a power supply unit on a power distribution unit for all the servers of the server rack with power capping in accordance with an embodiment of the present disclosure.

### DETAILED DESCRIPTION

As stated above, a data center is a physical facility that organizations use to house their critical applications and data. A data center's design is based on a network of computing and storage resources that enable the delivery of shared applications and data. The key components of a data center design include routers, switches, firewalls, storage systems, servers, and application-delivery controllers.

A data center may correspond to a high-availability data center, which is designed to be available at all times, including during both planned and unplanned outages. In high-availability data centers, such data centers employ a 2 N power-delivery system, where each server rack (rack specifically designed to hold and organize IT equipment, such as servers) is powered by two independent power distribution units (PDUs), where each PDU can power the entire load of the server rack to ensure 100% server availability in the event of a fault in one of the power feeds (e.g., power supply unit, which supplies power to the server, and the power distribution unit).

Under normal operating conditions, the power available for each server in the server rack is 200% of its rated power due to the redundancy overhead (two independent power distribution units). As a result, power oversubscription may be utilized to support demanding workloads whereby the peak power drawn by a server may exceed its N-mode rating as long as 2 N power is available.

Modern data centers improve resource utilization with power oversubscription. Power oversubscription of a data center refers to deploying more servers than allowed by the power limit. Power oversubscription is possible due to the statistically low likelihood of simultaneous peak power operation of multiple servers. As future servers become more energy proportional, the opportunity for greater power oversubscription increases.

However, when power oversubscription is enabled, there needs to be a mechanism to cap the power drawn by the servers of the server rack in the event of a failure in the power delivery system, such as the power supply unit (supplies power to the server) or the power distribution unit, which otherwise could result in circuit breaker overload leading to loss of power for the entire server rack.

Power capping is usually implemented at the rack or data center level. Unfortunately, such an approach is dependent on the availability of the management network which may not be available at the moment in time when power capping needs to be implemented.

The embodiments of the present disclosure provide a means for implementing power capping locally within each server to eliminate reliance on an external network. In one embodiment, a base management controller in each server of the server rack is configured to monitor for failures in the power supply units providing power to the components of the server. Upon detecting a failure in one or more of the power supply units, the base management controller determines the number of available power supply units supplying power to the components of the server. The base management controller then caps the power drawn by the server in proportion to the number of available power supply units in the server. In this manner, rack line cord and power distribution unit output power limits are not exceeded during various types of power faults that can occur in the server power supplies, the power distribution units or in the data center facility power distribution that feeds power to the power distribution units. That is, in this manner, circuit breakers are prevented from being triggered thereby preventing the loss of power for the entire server rack. A further discussion regarding these and other features is provided below.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

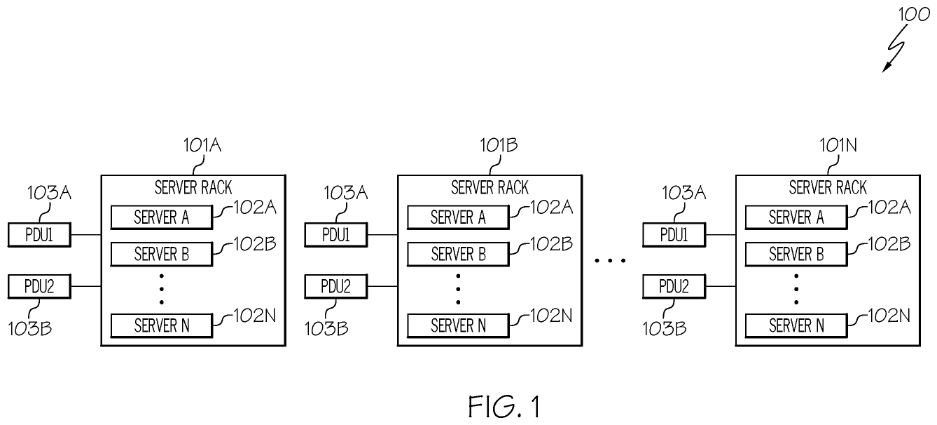

Referring now to the Figures in detail, FIG. 1 illustrates an embodiment of the present disclosure of a data center 100, such as a high-availability data center, for practicing the principles of the present disclosure.

As shown in FIG. 1, data center 100 includes server racks 101A-101N, where each server rack 101A-101N is designed to hold and organize IT equipment, such as servers 102A-102N (identified as “Server A” . . . “Server N,” respectively, in FIG. 1). Server racks 101A-101N may collectively or individually be referred to as server racks 101 or server rack 101, respectively. Servers 102A-102N may collectively or individually be referred to as servers 102 or server 102, respectively.

In one embodiment, each server rack 101 is powered by two independent power distribution units (PDUs) 103A-103B (identified as “PDU1,” and “PDU2,” respectively, in FIG. 1). Power distribution units 103A-103B may collectively or individually be referred to as power distribution units 103 or power distribution unit 103, respectively. In one embodiment, each power distribution unit 103 can power the entire load of server rack 101 to ensure 100% server availability in the event of a fault in one of the power feeds (e.g., power supply unit, which supplies power to server 102, power distribution unit 103, etc.).

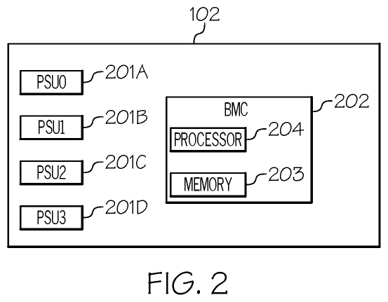

In one embodiment, each server 102 includes multiple power supply units configured to provide power to the components of server 102 as illustrated in FIG. 2.

Referring to FIG. 2, FIG. 2 illustrates an internal structure of a server (e.g., server 102) in accordance with an embodiment of the present disclosure.

As shown in FIG. 2, server 102 includes multiple power supply units (PSUs), such as power supply units 201A-201D (identified as “PSU0,” “PSU1,” “PSU2,” and “PSU3,” respectively, in FIG. 2), which are configured to provide power to the components of server 102. Power supply units 201A-201D may collectively or individually be referred to as power supply units 201 or power supply unit 201, respectively. While FIG. 2 illustrates four power supply units 201 being used to provide power to the components of server 102, any number of power supply units 201 may be utilized to provide power to the components of server 102.

In one embodiment, server 102 further includes a base management controller (BMC) 202 configured to monitor for failures of power supply units 201. In one embodiment, BMC 202 has its own memory 203 and processor 204 as well as persistent storage (not shown) and even dedicated network connections. In one embodiment, BMC 202 has input/output ports to connect to sensors (not shown) in server 102 and peripherals, such as fan and storage controllers. In one embodiment, BMC 202 is part of the intelligent platform management interface (IPMI). In one embodiment, BMC 202 is based on a reduced instruction set computer architecture. In one embodiment, BMC 202 is a system-on-a-chip, which is an integrated circuit that combines many elements, such as graphics and control log, on a single chip.

In one embodiment, BMC 202 prevents the loss of power to server rack 101 due to a failure in a power delivery system (e.g., power supply unit 201, power distribution unit 103). In one embodiment, BMC 202 prevents the loss of power to server rack 101 by detecting a failure in any of the monitored power supply units 201. Upon detecting a failure of one or more power supply units 201, BMC 202 is configured to determine the number of available power supply units 201. Upon determining the number of available power supply units 201, BMC 202 caps the power drawn by server 102 in proportion to the number of available power supply units 201 in server 102.

In one embodiment, the program for preventing the loss of power to server rack 101 due to a failure in a power delivery system is stored in memory 203, where the instructions of the program is executed by processor 204.

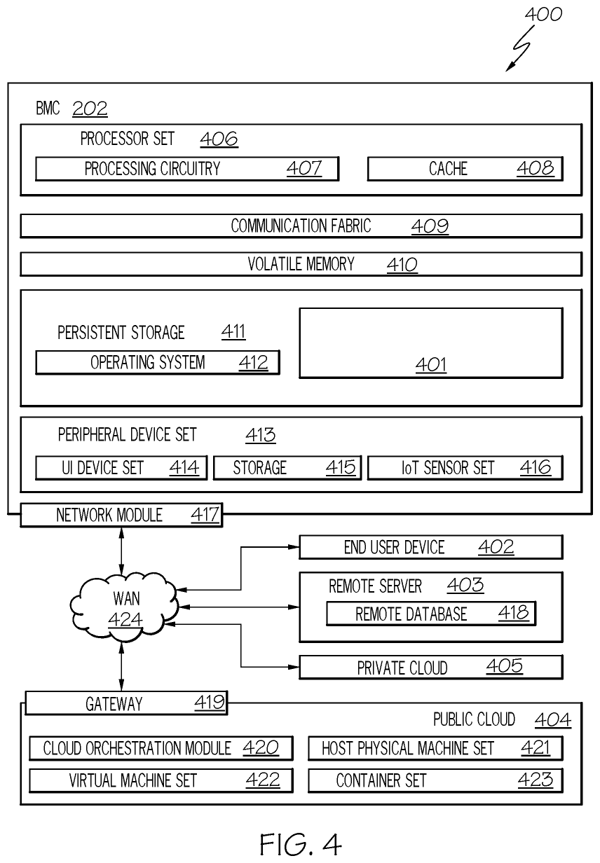

A further description of these and other features is provided further below. Furthermore, a description of the hardware configuration of BMC 202 is provided further below in connection with FIG. 4.

Returning to FIG. 1, in conjunction with FIG. 2, in one embodiment, each power distribution unit 103 operates using three-phase electric power, such as three-phase utility power. In one embodiment, each server 102 is supplied power from a different electrical phase from each power distribution unit 103. In one embodiment, each power distribution unit 103 distributes power to a pair of power supply units 201 from one circuit breaker to ensure that each pair of power supply units 201 operates from the same electrical phase.

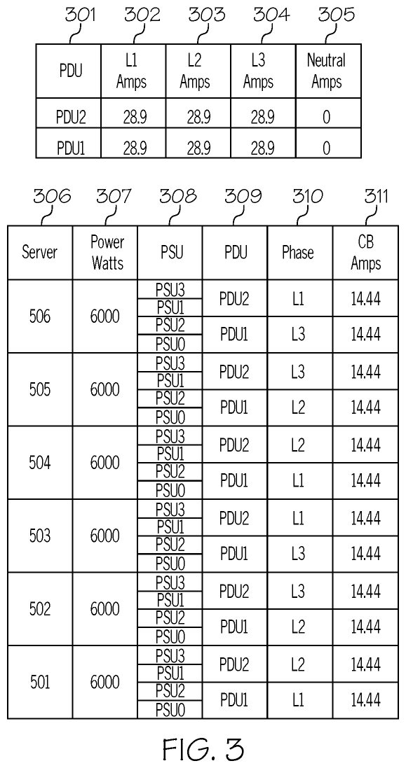

In one embodiment, the maximum power consumption of each server 102 is 6,000 Watts (W) and power supply units 201 within each server 102 are rated for 3,000 W to ensure that sufficient power is available during a fault, such as the loss of power distribution unit 103. In one embodiment, the line-to-line input voltage for power distribution unit 103 is around 360 Volts (V). Furthermore, in one embodiment, the power distribution unit circuit breaker currents along with the power distribution unit line cord currents for each phase (including the neutral) when there are no faults are illustrated in FIG. 3.

Referring to FIG. 3, FIG. 3 illustrates the power distribution unit currents for server rack 101 with six servers 102 when there are no faults in accordance with an embodiment of the present disclosure.

As shown in FIG. 3, when there are no faults, power distribution unit line cord currents (currents flowing to power distribution units 103 from a power source of data center 100, such as an uninterruptible power supply, a utility power supplier, or a generator or other secondary power source) correspond to 28.9 amps (A) for each of the three electrical phases (phases 1, 2 and 3) (identified as “L1,” “L2,” and “L3,” respectively, in FIG. 3) as listed under columns 302, 303, 304, respectively, for each power distribution unit 103, such as PDU1 103A and PDU2 103B, listed under column 301. Furthermore, FIG. 3 illustrates that there are 0 amps of current flowing to power distribution units 103A, 103B in the neutral wire as listed under column 305.

Additionally, as illustrated in FIG. 3, each server 102 (e.g., S01, S02, S03, S04, S05, S06) of server rack 101 listed under column 306 has a maximum power of 6,000 W (see column of power watts 307). FIG. 3 further includes a listing of the power supply units (PSUs) under column 308, power distribution units (PDUs) under column 309 and corresponding electrical phase under column 310 for each server 102 (e.g., server S06).

Furthermore, as discussed above, each power distribution unit 103 distributes power to a pair of power supply unites 201 from one circuit breaker (CB) to ensure that each pair of power supply units 201 operate from the same electrical phase. The amount of current flowing from such a circuit breaker (CB) when there is no fault is provided under column 311.

Additionally, as discussed above, each server 102 is supplied power from a different electrical phase from each power distribution unit 103. In the example of FIG. 3, server S01 is fed L1 from PDU1 103A and L2 from PDU2 103B. As further shown in FIG. 3, server S02 is fed L2 from PDU1 103A and L3 from PDU2 103B and server S03 is fed L3 from PDU1 103A and L1 from PDU2 103B. This pattern is repeated for servers S04-S06. By implementing such a power distribution scheme, the loss of a single phase common to both PDUs 103A, 103B ensures that it will only impact 2 of the 4 PSUs 201 per server 102.

In one embodiment, each power distribution unit 103 is fed from a 30 A circuit breaker and each pair of power supply units 201 is fed from a 20 A circuit breaker within power distribution unit 103. In the embodiment in which all six servers 102 of server rack 101 are operating at the 6,000 W maximum, and with the input voltage at the minimum of 360 V (line-to-line input voltage of power distribution unit 103), the currents shown in FIG. 3 are the highest possible for such a rack configuration yet remain well within the circuit breaker ratings.

Returning to FIG. 1, in conjunction with FIGS. 2-3, data center 100 is not to be limited in scope to any one particular network architecture. Data center 100 may include any number of server racks 101, servers 102, and power distribution units 103.

A discussion regarding the hardware configuration of base management controller (BMC) 202 (FIG. 2) is provided below in connection with FIG. 4.

Referring now to FIG. 4, in conjunction with FIG. 2, FIG. 4 illustrates an embodiment of the present disclosure of the hardware configuration of BMC 202 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 400 contains an example of an environment for the execution of at least some of the computer code (computer code for preventing the loss of power to a server rack due to a failure in a power delivery system, which is stored in block 401) involved in performing the disclosed methods, such as preventing the loss of power to a server rack due to a failure in a power delivery system. In addition to block 401, computing environment 400 includes, for example, BMC 202, network 424, such as a wide area network (WAN), end user device (EUD) 402, remote server 403, public cloud 404, and private cloud 405. In this embodiment, BMC 202 includes processor set 406 (including processing circuitry 407 and cache 408), communication fabric 409, volatile memory 410, persistent storage 411 (including operating system 412 and block 401, as identified above), peripheral device set 413 (including user interface (UI) device set 414, storage 415, and Internet of Things (IoT) sensor set 416), and network module 417. Remote server 403 includes remote database 418. Public cloud 404 includes gateway 419, cloud orchestration module 420, host physical machine set 421, virtual machine set 422, and container set 423.

Processor set 406 includes one, or more, computer processors of any type now known or to be developed in the future. Processing circuitry 407 may be distributed over multiple packages, for example, multiple, coordinated integrated circuit chips. Processing circuitry 407 may implement multiple processor threads and/or multiple processor cores. Cache 408 is memory that is located in the processor chip package(s) and is typically used for data or code that should be available for rapid access by the threads or cores running on processor set 406. Cache memories are typically organized into multiple levels depending upon relative proximity to the processing circuitry. Alternatively, some, or all, of the cache for the processor set may be located “off chip.” In some computing environments, processor set 406 may be designed for working with qubits and performing quantum computing.

Computer readable program instructions are typically loaded onto BMC 202 to cause a series of operational steps to be performed by processor set 406 of BMC 202 and thereby effect a computer-implemented method, such that the instructions thus executed will instantiate the methods specified in flowcharts and/or narrative descriptions of computer-implemented methods included in this document (collectively referred to as “the disclosed methods”). These computer readable program instructions are stored in various types of computer readable storage media, such as cache 408 and the other storage media discussed below. The program instructions, and associated data, are accessed by processor set 406 to control and direct performance of the disclosed methods. In computing environment 400, at least some of the instructions for performing the disclosed methods may be stored in block 401 in persistent storage 411.

Communication fabric 409 is the signal conduction paths that allow the various components of BMC 202 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 410 is any type of volatile memory now known or to be developed in the future. Examples include dynamic type random access memory (RAM) or static type RAM. Typically, the volatile memory is characterized by random access, but this is not required unless affirmatively indicated. In BMC 202, the volatile memory 410 is located in a single package and is internal to BMC 202, but, alternatively or additionally, the volatile memory may be distributed over multiple packages and/or located externally with respect to BMC 202.

Persistent Storage 411 is any form of non-volatile storage for computers that is now known or to be developed in the future. The non-volatility of this storage means that the stored data is maintained regardless of whether power is being drawn by BMC 202 and/or directly to persistent storage 411. Persistent storage 411 may be a read only memory (ROM), but typically at least a portion of the persistent storage allows writing of data, deletion of data and re-writing of data. Some familiar forms of persistent storage include magnetic disks and solid state storage devices. Operating system 412 may take several forms, such as various known proprietary operating systems or open source Portable Operating System Interface type operating systems that employ a kernel. The code included in block 401 typically includes at least some of the computer code involved in performing the disclosed methods.

Peripheral device set 413 includes the set of peripheral devices of BMC 202. Data communication connections between the peripheral devices and the other components of BMC 202 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 414 may include components such as a display screen, speaker, microphone, wearable devices (such as goggles and smart watches), keyboard, mouse, printer, touchpad, game controllers, and haptic devices. Storage 415 is external storage, such as an external hard drive, or insertable storage, such as an SD card. Storage 415 may be persistent and/or volatile. In some embodiments, storage 415 may take the form of a quantum computing storage device for storing data in the form of qubits. In embodiments where BMC 202 is required to have a large amount of storage (for example, where BMC 202 locally stores and manages a large database) then this storage may be provided by peripheral storage devices designed for storing very large amounts of data, such as a storage area network (SAN) that is shared by multiple, geographically distributed computers. IoT sensor set 416 is made up of sensors that can be used in Internet of Things applications. For example, one sensor may be a thermometer and another sensor may be a motion detector.

Network module 417 is the collection of computer software, hardware, and firmware that allows BMC 202 to communicate with other computers through WAN 424. Network module 417 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 417 are performed on the same physical hardware device. In other embodiments (for example, embodiments that utilize software-defined networking (SDN)), the control functions and the forwarding functions of network module 417 are performed on physically separate devices, such that the control functions manage several different network hardware devices. Computer readable program instructions for performing the disclosed methods can typically be downloaded to BMC 202 from an external computer or external storage device through a network adapter card or network interface included in network module 417.

WAN 424 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 402 is any computer system that is used and controlled by an end user (for example, a customer of an enterprise that operates BMC 202), and may take any of the forms discussed above in connection with BMC 202. EUD 402 typically receives helpful and useful data from the operations of BMC 202. For example, in a hypothetical case where BMC 402 is designed to provide a recommendation to an end user, this recommendation would typically be communicated from network module 417 of BMC 202 through WAN 424 to EUD 402. In this way, EUD 402 can display, or otherwise present, the recommendation to an end user. In some embodiments, EUD 402 may be a client device, such as thin client, heavy client, mainframe computer, desktop computer and so on.

Remote server 403 is any computer system that serves at least some data and/or functionality to BMC 202. Remote server 403 may be controlled and used by the same entity that operates BMC 202. Remote server 403 represents the machine(s) that collect and store helpful and useful data for use by other computers, such as BMC 202. For example, in a hypothetical case where BMC 202 is designed and programmed to provide a recommendation based on historical data, then this historical data may be provided to BMC 202 from remote database 418 of remote server 403.

Public cloud 404 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 404 is performed by the computer hardware and/or software of cloud orchestration module 420. The computing resources provided by public cloud 404 are typically implemented by virtual computing environments that run on various computers making up the computers of host physical machine set 421, which is the universe of physical computers in and/or available to public cloud 404. The virtual computing environments (VCEs) typically take the form of virtual machines from virtual machine set 422 and/or containers from container set 423. It is understood that these VCEs may be stored as images and may be transferred among and between the various physical machine hosts, either as images or after instantiation of the VCE. Cloud orchestration module 420 manages the transfer and storage of images, deploys new instantiations of VCEs and manages active instantiations of VCE deployments. Gateway 419 is the collection of computer software, hardware, and firmware that allows public cloud 404 to communicate through WAN 424.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 405 is similar to public cloud 404, except that the computing resources are only available for use by a single enterprise. While private cloud 405 is depicted as being in communication with WAN 424 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 404 and private cloud 405 are both part of a larger hybrid cloud.

As stated above, a data center may correspond to a high-availability data center, which is designed to be available at all times, including during both planned and unplanned outages. In high-availability data centers, such data centers employ a 2 N power-delivery system, where each server rack (rack specifically designed to hold and organize IT equipment, such as servers) is powered by two independent power distribution units (PDUs), where each PDU can power the entire load of the server rack to ensure 100% server availability in the event of a fault in one of the power feeds (e.g., power supply unit, which supplies power to the server, and the power distribution unit). Under normal operating conditions, the power available for each server in the server rack is 200% of its rated power due to the redundancy overhead (two independent power distribution units). As a result, power oversubscription may be utilized to support demanding workloads whereby the peak power drawn by a server may exceed its N-mode rating as long as 2 N power is available. Modern data centers improve resource utilization with power oversubscription. Power oversubscription of a data center refers to deploying more servers than allowed by the power limit. Power oversubscription is possible due to the statistically low likelihood of simultaneous peak power operation of multiple servers. As future servers become more energy proportional, the opportunity for greater power oversubscription increases. However, when power oversubscription is enabled, there needs to be a mechanism to cap the power drawn by the servers of the server rack in the event of a failure in the power delivery system, such as the power supply unit (supplies power to the server) or the power distribution unit, which otherwise could result in circuit breaker overload leading to loss of power for the entire server rack. Power capping is usually implemented at the rack or data center level. Unfortunately, such an approach is dependent on the availability of the management network which may not be available at the moment in time when power capping needs to be implemented.

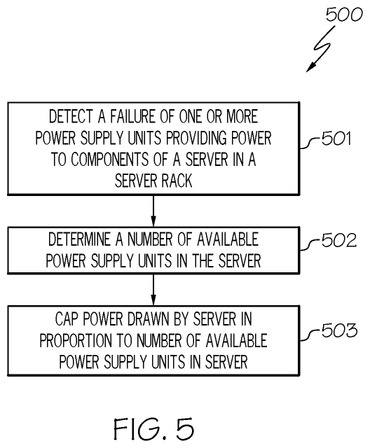

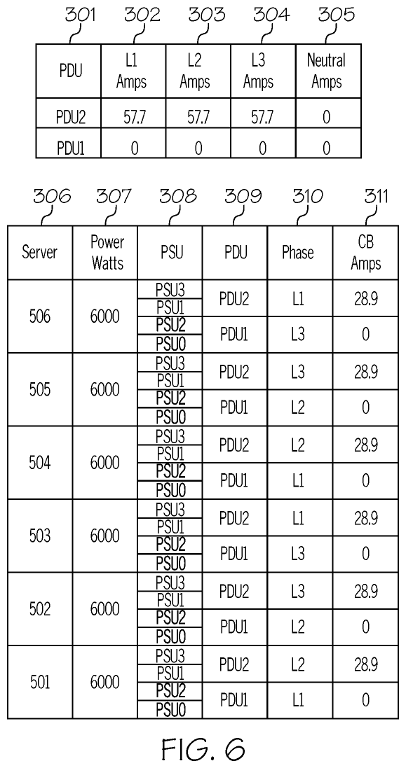

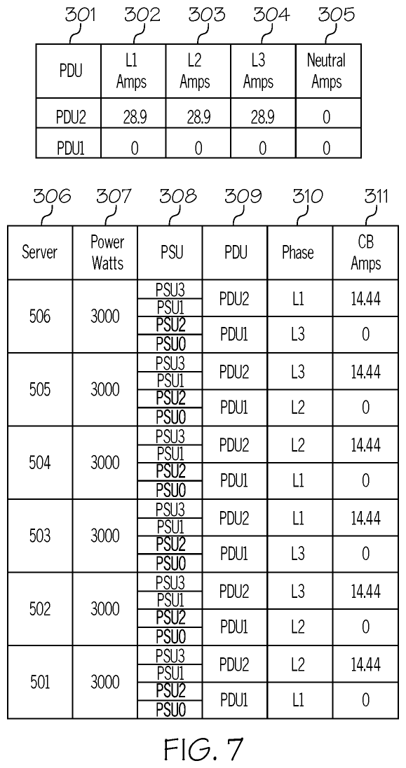

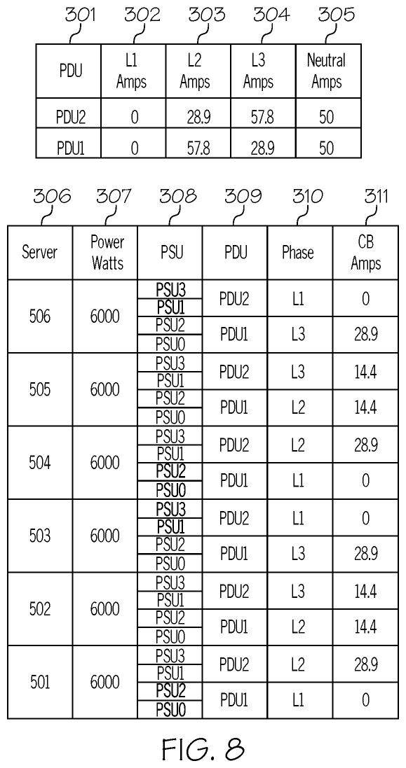

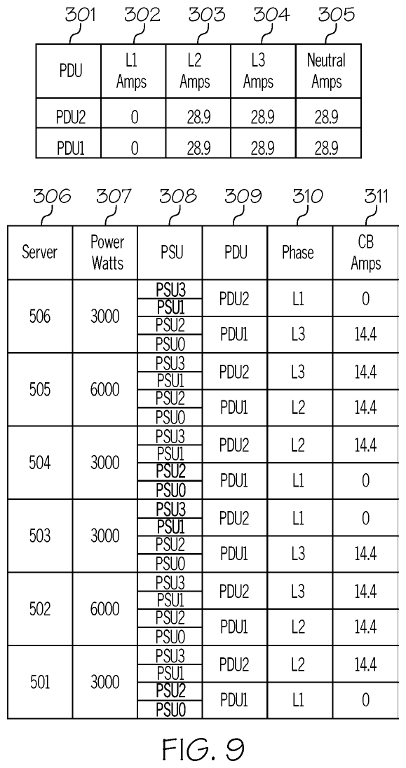

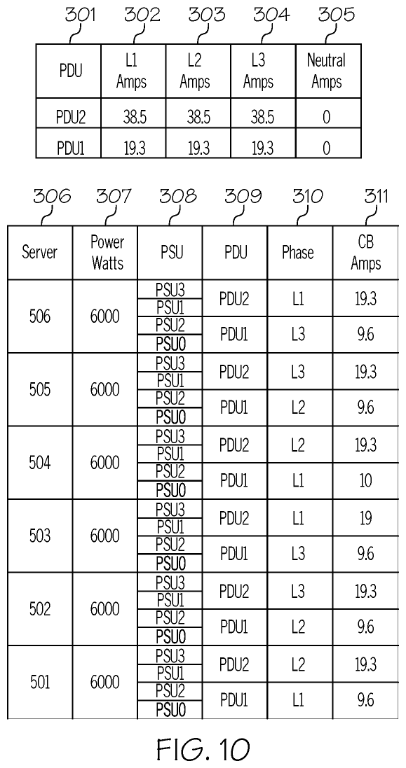

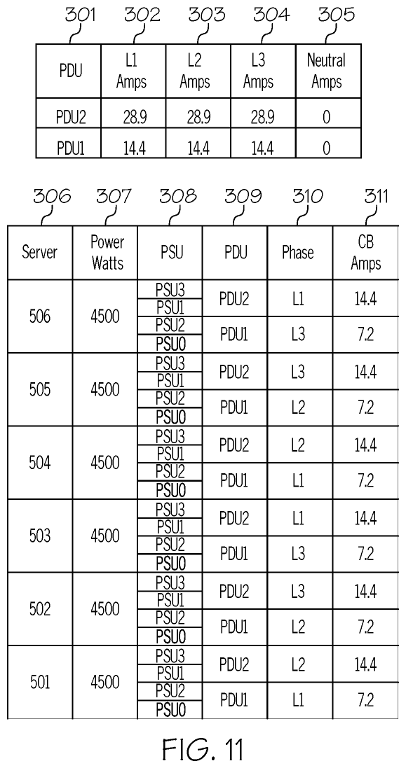

The embodiments of the present disclosure provide a means for implementing power capping locally within each server to eliminate reliance on an external network as discussed below in connection with FIGS. 5-11. FIG. 5 is a flowchart of a method for preventing loss of power to a server rack (e.g., server rack 101 of FIG. 1) due to a failure in the power delivery system (e.g., power supply unit 201, power distribution unit 103). FIG. 6 illustrates the case of a fault of the power distribution unit with no power capping. FIG. 7 illustrates the case of a fault of the power distribution unit with power capping. FIG. 8 illustrates the case of the loss of a line cord phase on both power distribution units with no power capping. FIG. 9 illustrates the case of the loss of a line cord phase on both power distribution units with power capping. FIG. 10 illustrates the case of a fault of a power supply unit on a power distribution unit for all the servers of the server rack with no power capping. FIG. 11 illustrates the case of a fault of a power supply unit on a power distribution unit for all the servers of the server rack with power capping.

As stated above, FIG. 5 is a flowchart of a method 500 for preventing loss of power to a server rack (e.g., server rack 101 of FIG. 1) due to a failure in the power delivery system (e.g., power supply unit 201, power distribution unit 103) in accordance with an embodiment of the present disclosure.

Referring to FIG. 5, in conjunction with FIGS. 1-4, in operation 501, BMC 202 detects a failure of one or more power supply units 201 (e.g., power supply units 201A, 201B), which provide power to the components of server 102 in server rack 101.

In one embodiment, BMC 202 continuously monitors the status of power supply units 201. In one embodiment, BMC 202 uses a sensor(s) to measure the operating functionality of power supply unit 201. Upon detecting a failure in the functioning of power supply unit 201, BMC 202 detects a failure in such a power supply unit 201.

Furthermore, in one embodiment, BMC 202 stays in constant communication with each of the power supply units 201 of server 102. When a loss of communication occurs with a power supply unit 201, such as from a failure of power supply unit 201, BMC 202 classifies such a loss of communication as being a failure or fault of power supply unit 201.

In operation 502, BMC 202 determines the number of available power supply units 201 (e.g., power supply units 201C, 201D) in server 102.

In operation 503, BMC 202 caps the power drawn by server 102 in proportion to the number of available power supply units 201 in server 102. For example, if two of the four power supply units 201 are available after detecting the failure of one or more power supply units 201, then the power to server 102 will be capped by the number of available power supply units 201 divided by the total number of power supply units 201 ( 2/4 or ½) of the maximum power consumption (e.g., 6,000 W), such as to 3,000 W when the maximum power consumption is 6,000 W and the number of available power supply units 201 is two out of a total of four power supply units 201.

In this manner, rack line cord and power distribution unit output power limits are not exceeded during various types of power faults that can occur in the server power supplies, the power distribution units or in the data center facility power distribution that feeds power to the power distribution units. That is, in this manner, circuit breakers are prevented from being triggered thereby preventing the loss of power for the entire server rack (e.g., server rack 101).

A discussion illustrating method 500 preventing the loss of power for the entire server rack (e.g., server rack 101) by preventing the circuit breakers from being triggered is provided below in connection with FIGS. 6-11, which illustrate various cases or scenarios of the different power faults that can occur.

Referring now to FIG. 6, FIG. 6 illustrates the case of a fault of the power distribution unit with no power capping in accordance with an embodiment of the present disclosure.

The currents for PDU2 103B after the failure of PDU1 103A are shown in FIG. 6. Initially, the currents double, such as having the PDU circuit breaker (CB) current increasing from 14.4 A to 28.9 A and the line cord phase currents increasing from 28.9 A to 57.7 A. Without power capping, the PDU circuit breakers, which may be rated for 20 A, and the line cord circuit breaker, which may be rated for 30 A, will be eventually tripped. Since such circuit breakers will not be tripped instantaneously given the time-delay characteristics (e.g., on the order of seconds or tens of seconds) inherent in a circuit breaker, the tripping of the circuit breakers may be prevented by capping the power drawn by server 102 as discussed below.

As discussed above, BMC 202 continuously monitors the status of each power supply unit 201 in server 102 and therefore detects when a power supply unit 201 fails. When a power distribution unit 103 fails, power supply units 201 that were provided power from such a power distribution unit 103 also fail. As a result of such power supply units 201 failing, there is a loss of communication with BMC 202. Such a loss of communication results in BMC 202 classifying such power supply units 201 as failing.

As illustrated in FIG. 6, due to the failure of PDU1 103A, two of the four power supply units 201 fail (e.g., PSU0 201A and PSU2 201C). After detecting such failed power supply units 201, BMC 202 determines the number of available power supply units 201, which in this case corresponds to two of the four power supply units 201, such as PSU1 201B and PSU3 201D. BMC 202 then proceeds to cap the power drawn by server 102 in proportion to the number of available power supply units 201 in server 102. For example, the maximum power consumption of server 102 will now be capped to the number of available power supply units 201 divided by the total number of power supply units 201 ( 2/4 or ½) times the maximum power consumption (e.g., 6,000 W), which equals 3,000 W as illustrated in FIG. 7.

FIG. 7 illustrates the case of a fault of the power distribution unit with power capping in accordance with an embodiment of the present disclosure.

As illustrated in FIG. 7, once power capping has been invoked by BMC 202, the PDU2 currents are reduced to their pre-fault values (see FIG. 3).

For example, the currents supplied by PDU2 103B to the available power supply units 201 (e.g., power supply units 201B, 201D) are reduced (e.g., 14.44 A from 28.9 A) to prevent triggering of the PDU circuit breaker (rated for 20 A). Furthermore, the currents of the line cord phase, for each of the three phases, are reduced (e.g., 28.9 A from 57.7 A) to prevent triggering of the line cord circuit breaker (rated for 30 A).

Referring now to FIG. 8, FIG. 8 illustrates the case of the loss of a line cord phase on both power distribution units with no power capping in accordance with an embodiment of the present disclosure.

In particular, FIG. 8 illustrates the currents after the loss of phase current L1 on both power distribution units 103 (e.g., power distribution units 103A, 103B). In this case, only four of the six servers 102 are affected since two of the six servers 102 do not rely on phase current L1. Initially, one of the phase currents in each line cord is increased to 57.8 A from 28.9 A with 50 A flowing in the neutral wire. Furthermore, the PDU circuit breaker (CB) current increases from 14.4 A to 28.9 A for two of the four power supply units 201 that do not receive phase current L1in certain situations where the other two power supply units 201 receive phase current L1. Without power capping, the PDU circuit breakers, which may be rated for 20 A, and the line cord circuit breaker, which may be rated for 30 A, will be eventually tripped. Since such circuit breakers will not be tripped instantaneously given the time-delay characteristics (e.g., on the order of seconds or tens of seconds) inherent in a circuit breaker, the tripping of the circuit breakers may be prevented by capping the power drawn by server 102 as discussed below.

As discussed above, BMC 202 continuously monitors the status of each power supply unit 201 in server 102 and therefore detects when a power supply unit 201 fails. When a power distribution unit 103 fails, power supply units 201 that were provided power from such a power distribution unit 103 also fail. As a result of such power supply units 201 failing, there is a loss of communication with BMC 202. Such a loss of communication results in BMC 202 classifying such power supply units 201 as failing.

As illustrated in FIG. 8, due to the loss of phase current L1 on both power distribution units 103, two of the four power supply units 201 fail in particular servers 102 that receive phase currents L1. After detecting such failed power supply units 201, BMC 202 determines the number of available power supply units 201, which in this case corresponds to two of the four power supply units 201. BMC 202 then proceeds to cap the power drawn by server 102 in proportion to the number of available power supply units 201 in server 102. For example, the maximum power consumption of server 102 will now be capped to the number of available power supply units 201 divided by the total number of power supply units 201 ( 2/4 or ½) times the maximum power consumption (e.g., 6,000 W), which equals 3,000 W as illustrated in FIG. 9.

FIG. 9 illustrates the case of the loss of a line cord phase on both power distribution units with power capping in accordance with an embodiment of the present disclosure.

As illustrated in FIG. 9, once power capping has been invoked by BMC 202, the affected servers 102 are capped to a maximum power consumption of 3,000 W. As a result, the PDU currents are reduced to a safe value within the ratings of their respective circuit breakers.

For example, the currents supplied by PDUs 103 that previously exceeded 20 A are now reduced to 14.44 A from 28.9 A thereby preventing the triggering of the PDU circuit breaker (rated for 20 A). Furthermore, the phase currents in the line cord that previously exceeded 30 A are reduced to 28.9 A from 57.8 A to prevent triggering of the line cord circuit breaker (rated for 30 A).

Referring now to FIG. 10, FIG. 10 illustrates the case of a fault of a power supply unit on a power distribution unit for all the servers of the server rack with no power capping in accordance with an embodiment of the present disclosure.

As shown in FIG. 10, FIG. 10 illustrates the currents after a power supply unit fault on PDU1 103A for all servers 102 without power capping. In this case, while the PDU2 circuit breaker current is within its 20 A rating, the line cord current is now 38.5 A, which exceeds the line cord circuit breaker rating of 30 A.

As discussed above, BMC 202 continuously monitors the status of each power supply unit 201 in server 102 and therefore detects when a power supply unit 201 fails. As a result of a power supply unit 201 failing, there is a loss of communication with BMC 202. Such a loss of communication results in BMC 202 classifying such power supply units 201 as failing.

As illustrated in FIG. 10, there is a PSU fault (e.g., PSU0 201A) on PDU1 103A for all servers 102. After detecting such a failed power supply unit 201, BMC 202 determines the number of available power supply units 201, which in this case correspond to three of the four power supply units 201. BMC 202 then proceeds to cap the power drawn by server 102 in proportion to the number of available power supply units 201 in server 102. For example, the maximum power consumption of server 102 will now be capped to the number of available power supply units 201 divided by the total number of power supply units 201 (¾) times the maximum power consumption (e.g., 6,000 W), which equals 4,500 W as illustrated in FIG. 11.

FIG. 11 illustrates the case of a fault of a power supply unit on a power distribution unit for all the servers of the server rack with power capping in accordance with an embodiment of the present disclosure.

As illustrated in FIG. 11, once power capping has been invoked by BMC 202, servers 102 are capped to a maximum power consumption of 4,500 W. As a result, the line cord current for PDU2 103B is reduced to 28.9 A from 38.5 A thereby preventing the triggering of the line cord circuit breaker (rated for 30 A).

Furthermore, as illustrated in FIG. 11, the currents supplied by PDUs 103 have been reduced, such as from 19.3 A to 14.4 A, 9.6 A to 7.2 A, 10 A to 7.2 A and 19 A to 14.4 A.

As a result of the foregoing, the principles of the present disclosure ensure that the rack line cord and power distribution unit output power limits are not exceeded during various types of power faults that can occur in the server power supplies, the power distribution units or in the data center facility power distribution that feeds power to the power distribution units. That is, the principles of the present disclosure prevent circuit breakers from being triggered thereby preventing the loss of power for the entire server rack.

Furthermore, the principles of the present disclosure ensure that the circuit breakers in the power supply unit and the power distribution unit do not trip even when the management network is not available.

Additionally, the principles of the present disclosure improve the technology or technical field involving data centers.

As discussed above, a data center may correspond to a high-availability data center, which is designed to be available at all times, including during both planned and unplanned outages. In high-availability data centers, such data centers employ a 2 N power-delivery system, where each server rack (rack specifically designed to hold and organize IT equipment, such as servers) is powered by two independent power distribution units (PDUs), where each PDU can power the entire load of the server rack to ensure 100% server availability in the event of a fault in one of the power feeds (e.g., power supply unit, which supplies power to the server, and the power distribution unit). Under normal operating conditions, the power available for each server in the server rack is 200% of its rated power due to the redundancy overhead (two independent power distribution units). As a result, power oversubscription may be utilized to support demanding workloads whereby the peak power drawn by a server may exceed its N-mode rating as long as 2 N power is available. Modern data centers improve resource utilization with power oversubscription. Power oversubscription of a data center refers to deploying more servers than allowed by the power limit. Power oversubscription is possible due to the statistically low likelihood of simultaneous peak power operation of multiple servers. As future servers become more energy proportional, the opportunity for greater power oversubscription increases. However, when power oversubscription is enabled, there needs to be a mechanism to cap the power drawn by the servers of the server rack in the event of a failure in the power delivery system, such as the power supply unit (supplies power to the server) or the power distribution unit, which otherwise could result in circuit breaker overload leading to loss of power for the entire server rack. Power capping is usually implemented at the rack or data center level. Unfortunately, such an approach is dependent on the availability of the management network which may not be available at the moment in time when power capping needs to be implemented.

Embodiments of the present disclosure improve such technology by utilizing a base management controller in a server of the server rack to monitor for failures in the power supply units providing power to the components of the server. Upon detecting a failure in one or more of the power supply units, the base management controller determines the number of available power supply units supplying power to the components of the server. The base management controller then caps the power drawn by the server in proportion to the number of available power supply units in the server. In this manner, rack line cord and power distribution unit output power limits are not exceeded during various types of power faults that can occur in the server power supplies, the power distribution units or in the data center facility power distribution that feeds power to the power distribution units. That is, in this manner, circuit breakers are prevented from being triggered thereby preventing the loss of power for the entire server rack. Furthermore, in this manner, there is an improvement in the technical field involving data centers.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for preventing loss of power to a server rack due to a failure in a power delivery system, the method comprising:
detecting a failure of one or more power supply units providing power to components of a server of the server rack;
determining a number of available power supply units in the server in response to detecting the failure of the one or more power supply units; and
capping power drawn by the server in proportion to the number of available power supply units in the server.

2. The method as recited in claim 1, wherein the failure of the one or more supply units is caused by a failure of a first power distribution unit of two power distribution units connected to 2 the server rack, wherein each of the two power distribution units is configured to distribute power to the server rack, wherein each of the two power distribution units is further configured to power an entire load of the server rack.

3. The method as recited in claim 2, wherein, in response to the capping of power drawn by the server, currents supplied by a second power distribution unit of the two power distribution units to the available power supply units is reduced to prevent triggering of a circuit breaker.

4. The method as recited in claim 2, wherein, in response to the capping of power drawn by the server, phase currents of a line cord received by a second power distribution unit of the two power distribution units are reduced to prevent triggering of a circuit breaker.

5. The method as recited in claim 1, wherein the failure of the one or more supply units is caused by a failure of receipt of current of a first phase of a line cord by two power distribution units connected to the server rack, wherein each of the two power distribution units is configured to distribute power to the server rack, wherein each of the two power distribution units is further configured to power an entire load of the server rack.

6. The method as recited in claim 5, wherein, in response to the capping of power drawn by the server, currents of a second or a third phase of the line cord received by one of the two power distribution units are reduced to prevent triggering of a circuit breaker.

7. The method as recited in claim 5, wherein, in response to the capping of power drawn by the server, currents supplied by one of the two power distribution units to the available power supply units is reduced to prevent triggering of a circuit breaker.

8. The method as recited in claim 1, wherein, in response to the capping of power drawn by the server, currents supplied by two power distribution units to the available power supply units is reduced to prevent triggering of a circuit breaker, wherein each of the two power distribution units is configured to distribute power to the server rack, wherein each of the two power distribution units is further configured to power an entire load of the server rack.

9. The method as recited in claim 1, wherein, in response to the capping of power drawn by the server, currents of a first, a second, and a third phase of a line cord received by two power distribution units are reduced to prevent triggering of a circuit breaker, wherein each of the two power distribution units is configured to distribute power to the server rack, wherein each of the two power distribution units is further configured to power an entire load of the server rack.

10. A server rack, comprising:
a plurality of servers, wherein each server of the plurality of servers is powered by a first power distribution unit and a second power distribution unit, wherein each server of the plurality of servers comprises a plurality of power supply units configured to provide power to components of the server, wherein each of the first and the second power distribution units operates using three-phase electric power, wherein each of the first and the second power distribution units distributes power to each pair of power supply units of the plurality of power supply units from one circuit breaker to ensure that each pair of power supply units of the plurality of power supply units operates from a same electrical phase.

11. The server rack as recited in claim 10, wherein each of the plurality of servers comprises a base management controller configured to monitor a failure of the plurality of power supply units, wherein, in response to detecting a failure of one or more of the plurality of power supply units, the base management controller is configured to determine a number of available power supply units in the server and cap power drawn by the server in proportion to the number of available power supply units in the server.

12. A base management controller of a server, comprising:
a memory for storing a computer program for preventing loss of power to a server rack due to a failure in a power delivery system; and
a processor connected to the memory, wherein the processor is configured to execute program instructions of the computer program comprising: 5
detecting a failure of one or more power supply units providing power to components of a server of the server rack;
determining a number of available power supply units in the server in response to detecting the failure of the one or more power supply units; and
capping power drawn by the server in proportion to the number of available power supply units in the server.

13. The base management controller of the server as recited in claim 12, wherein the failure of the one or more supply units is caused by a failure of a first power distribution unit of two power distribution units connected to the server rack, wherein each of the two power distribution units is configured to distribute power to the server rack, wherein each of the two power distribution units is further configured to power an entire load of the server rack.

14. The base management controller of the server as recited in claim 13, wherein, in response to the capping of power drawn by the server, currents supplied by a second power distribution unit of the two power distribution units to the available power supply units is reduced to prevent triggering of a circuit breaker.

15. The base management controller of the server as recited in claim 13, wherein, in response to the capping of power drawn by the server, phase currents of a line cord received by a second power distribution unit of the two power distribution units are reduced to prevent triggering of a circuit breaker.

16. The base management controller of the server as recited in claim 12, wherein the failure of the one or more supply units is caused by a failure of receipt of current of a first phase of a line cord by two power distribution units connected to the server rack, wherein each of the two power distribution units is configured to distribute power to the server rack, wherein each of the two power distribution units is further configured to power an entire load of the server rack.

17. The base management controller of the server as recited in claim 16, wherein, in response to the capping of power drawn by the server, currents of a second or a third phase of the line cord received by one of the two power distribution units are reduced to prevent triggering of a circuit breaker.

18. The base management controller of the server as recited in claim 16, wherein, in response to the capping of power drawn by the server, currents supplied by one of the two power distribution units to the available power supply units is reduced to prevent triggering of a circuit breaker.

19. The base management controller of the server as recited in claim 12, wherein, in response to the capping of power drawn by the server, currents supplied by two power distribution units to the available power supply units is reduced to prevent triggering of a circuit breaker, wherein each of the two power distribution units is configured to distribute power to the server rack, wherein each of the two power distribution units is further configured to power an entire load of the server rack.

20. The base management controller of the server as recited in claim 12, wherein, in response to the capping of power drawn by the server, currents of a first, a second, and a third phase of a line cord received by two power distribution units are reduced to prevent triggering of a circuit breaker, wherein each of the two power distribution units is configured to distribute power to the server rack, wherein each of the two power distribution units is further configured to power an entire load of the server rack.
